(19) United States
(12) Patent Application Publication
(10) Pub. No.: US 2023/0408298 A1
(43) Pub. Date: Dec. 21, 2023

(54) ANGLE SENSOR AND ANGLE SENSOR MODULE

(71) Applicant: Murata Manufacturing Co., Ltd., Nagaokakyo-shi (JP)

(72) Inventor: Katsumi FUJIMOTO, Nagaokakyo-shi (JP)

(21) Appl. No.: 18/459,561

(22) Filed: Sep. 1, 2023

Related U.S. Application Data
(63) Continuation of application No. PCT/JP2022/014302, filed on Mar. 25, 2022.

(30) Foreign Application Priority Data
Apr. 15, 2021 (JP) 2021-069192

(51) Int. Cl. G01D 5/20

(52) U.S. Cl. CPC G01D 5/2073

(57) ABSTRACT

An angle sensor is provided that includes a multilayer substrate having multiple layers, a drive coil in the multilayer substrate, and first and second detection coils, which can be two-phase detection coils, that are provided in the multilayer substrate. Each of the multiple layers in the multilayer substrate has a first main surface and a second main surface facing each other. The drive coil and the first and second detection coils are provided on respective different main surfaces, among the first main surfaces and the second main surfaces of the multiple layers in the multilayer substrate.

### CROSS REFERENCE TO RELATED APPLICATIONS

This application is a continuation of International Application No. PCT/JP2022/014302, filed Mar. 25, 2022, which claims priority to Japanese Patent Application No. 2021-069192, filed Apr. 15, 2021, the entire contents of each of which are hereby incorporated by reference in their entirety.

### TECHNICAL FIELD

The present invention relates to angle sensors and angle sensor modules.

### BACKGROUND

Conventionally, angle sensors have been used to detect angles of targets in various appliances, such as motor shafts, gears, and pulleys. For example, U.S. Pat. No. 4,737,698 (hereinafter “Patent Document 1”) described below discloses an example of a sensor for detecting an angle or a position of a target using eddy currents. The sensor described in Patent Document 1 includes a drive coil and two-phase detection coils. The drive coil generates a signal at a constant frequency. The detection coils receive the signal generated from the drive coil. If a target, which is a conductor, approaches the surfaces of the detection coils, this causes eddy currents to flow through the target, thereby inducing an electric power loss. This induces changes of the detected voltages. When there is a deviation in phase between the spatial positions of the two-phase detection coils, there is a difference in amplitude between the signals, according to the position of the target. When the deviation in phase between the spatial positions of the two-phase detection coils is set to 90°, these two-phase detection coils can reflect a sine signal and a cosine signal. By utilizing this configuration, the absolute position of the target can be calculated from the difference in amplitude therebetween with respect to the position of the target.

Further, Patent Document 1 discloses an example of an angle sensor incorporating two-phase detection coils disposed on a disk-shaped substrate. In this case, if a target is rotated, this induces a difference in amplitude between the signals detected by the two-phase detection coils according to the angle of the target. This enables measuring the absolute angle of the target.

Moreover, U.S. Pat. No. 10,585,149 (hereinafter “Patent Document 2”) discloses an example of shapes and placements of a drive coil and two-phase detection coils in an angle sensor.

However, in the angle sensors described in Patent Documents 1 and 2, the drive coil is positioned outside the detection coils with a certain gap interposed therebetween, in order to prevent short-circuiting between the drive coil and the detection coils. Therefore, it is difficult to reduce the outer diameter of the drive coil, which makes it difficult to reduce the overall size of the angle sensor.

### SUMMARY OF THE INVENTION

Accordingly, it is an object of the present invention to provide an angle sensor and an angle sensor module that are effectively downsized.

In an exemplary aspect, an angle sensor is provided that includes a multilayer substrate having a plurality of layers, a drive coil disposed in the multilayer substrate, and two-phase detection coils disposed in the multilayer substrate. In the exemplary aspect, each of the plurality of layers in the multilayer substrate has main surfaces facing each other. Moreover, the drive coil and the detection coils are provided on different main surfaces, respectively, of the main surfaces of the plurality of layers.

An angle sensor module according to the present invention includes a mounting substrate, the angle sensor structured according to the present invention and, provided on the mounting substrate, and an angle detection circuit provided on the mounting substrate and electrically connected to the angle sensor.

Accordingly, the exemplary aspects of the present invention provide an angle sensor and an angle sensor module that are effectively downsized.

### BRIEF DESCRIPTION OF DRAWINGS

FIG. 1 is a schematic front elevational sectional view of an angle sensor according to a first exemplary embodiment.

FIG. 2 is an exploded perspective view of an angle sensor according to the first exemplary embodiment.

FIG. 3 is a front elevational view of an angle sensor and a target according to the first exemplary embodiment.

FIG. 4 is a view simply illustrating the structure of electrodes of a drive coil, a first detection coil and a second detection coil in a comparative example.

FIG. 5 is a view illustrating the structure of electrodes of a first detection coil and a second detection coil according to the first exemplary embodiment.

FIG. 6 is a view illustrating the structure of electrodes of a first detection coil and a second detection coil in a modification example according to the first exemplary embodiment.

FIG. 7 is a schematic front elevational sectional view of an angle sensor according to a second exemplary embodiment.

FIG. 8 is a schematic front elevational sectional view of an angle sensor according to a third exemplary embodiment.

FIG. 9 is a perspective view of an angle sensor according to a fourth exemplary embodiment.

FIG. 10 is a perspective view of an angle sensor in a first modification example according to the fourth exemplary embodiment.

FIG. 11 is a perspective view of an angle sensor in a second modification example according to the fourth exemplary embodiment.

FIG. 12 is a perspective view of an angle sensor module according to a fifth exemplary embodiment.

FIG. 13 is a simplified sectional view of an angle sensor module according to a sixth exemplary embodiment.

### DETAILED DESCRIPTION

Hereinafter, the present invention will be clarified by describing exemplary embodiments with reference to the drawings.

It is noted that each of the embodiments described in the present specification is merely illustrative and exemplary, and portions of structures in different embodiments can be replaced or combined with each other.

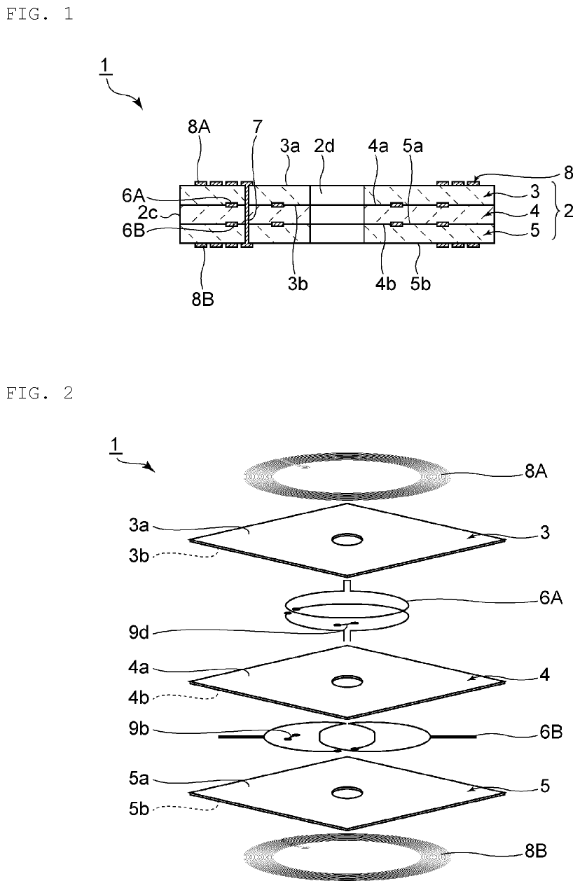

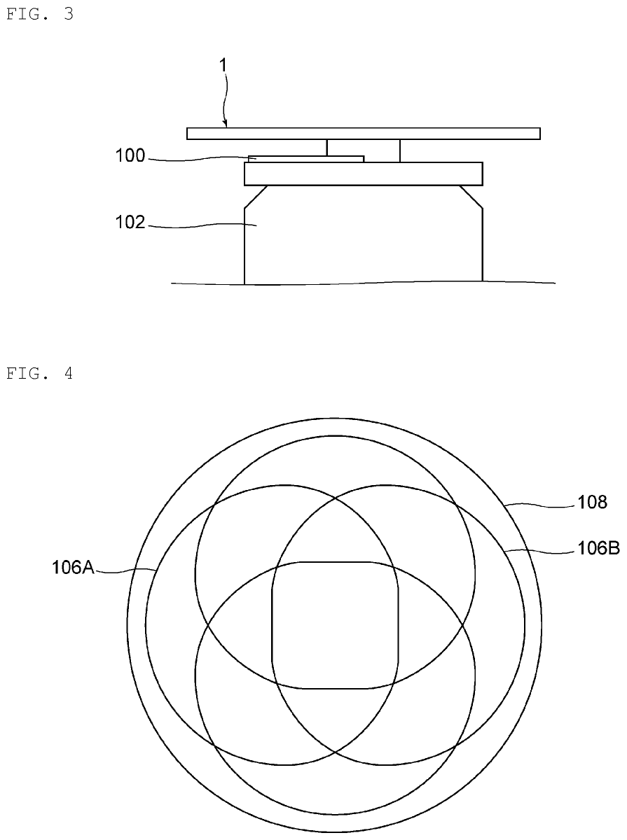

FIG. 1 is a schematic front elevational sectional view of an angle sensor according to a first exemplary embodiment. FIG. 2 is an exploded perspective view of an angle sensor according to the first exemplary embodiment. FIG. 3 is a front elevational view of an angle sensor and a target according to the first exemplary embodiment.

In operation, the angle sensor 1 illustrated in FIGS. 1 and 2 is configured to detect a rotational angle of a target. As illustrated in FIG. 1, the angle sensor 1 includes a multilayer substrate 2, a first detection coil 6A and a second detection coil 6B, which are two-phase detection coils in the exemplary aspect, and a drive coil 8. The drive coil 8 and the two-phase detection coils are provided in the multilayer substrate 2. The drive coil 8 is connected to an external LC oscillation circuit and is configured to constantly generate a magnetic flux. FIG. 3 illustrates a target 100 that is attached to a rotatable shaft 102. If the target 100 is brought close to the angle sensor 1, an eddy current flows through the target 100. Then, the eddy current increases or decreases, depending on the rotational angle of the target 100. The first detection coil 6A and the second detection coil 6B illustrated in FIG. 1 are configured to detect an increase or decrease of the eddy current in each phase. Thus, the rotational angle of the target 100 is detected. Preferably, in an exemplary aspect, one of the first detection coil 6A and the second detection coil 6B is configured to detect a sine wave, while the other is configured to detect a cosine wave. Hereinafter, a specific structure of the angle sensor 1 will be described.

Returning to FIG. 1, the multilayer substrate 2 includes a first layer 3, a second layer 4, and a third layer 5, which can generally be considered a plurality of layers. The first layer 3 has a first main surface 3a and a second main surface 3b that face each other. Similarly, the second layer 4 has a first main surface 4a and a second main surface 4b, and the third layer 5 also has a first main surface 5a and a second main surface 5b. The second layer 4 is stacked on the first main surface 5a of the third layer 5. The first layer 3 is stacked on the first main surface 4a of the second layer 4. It should be appreciated that the number of layers in the multilayer substrate 2 is not limited to three, and may be four or more in alternative aspects.

The multilayer substrate 2 has one main surface and the other main surface, and a side surface 2c. According to the present embodiment with the three layers 3, 4, and 5, one main surface of the multilayer substrate 2 forms the first main surface 3a of the first layer 3 and the other main surface of the multilayer substrate 2 forms the second main surface 5b of the third layer 5. The one main surface and the other main surface of the multilayer substrate 2 face each other. The side surface 2c of the multilayer substrate 2 is connected to the one main surface and the other main surface of the multilayer substrate 2. The multilayer substrate 2 has a rectangular shape in a plan view. However, it is noted that the shape of the multilayer substrate 2 in a plan view is not limited to that described above, and may be, for example, a polygon other than a rectangle, a circle, an ellipse, or the like. For purposes of this disclosure, the term “a plan view” refers to a view in a direction from above in FIG. 2. More specifically, a plan view refers to a view in the direction from the first layer 3 side toward the third layer 5 side, for example.

The drive coil 8 includes a plurality of coil portions, and a through electrode 7. More specifically, the plurality of coil portions includes a first coil portion 8A and a second coil portion 8B. The first coil portion 8A is on the first main surface 3a of the first layer 3 and the second coil portion 8B is on the second main surface 5b of the third layer 5. The drive coil 8 may also have three or more layered coil portions in alternative aspects. The first coil portion 8A and the second coil portion 8B are connected to each other via the through electrode 7. Incidentally, the through electrode 7 penetrates (e.g., extends through) the first layer 3, the second layer 4, and the third layer 5. However, the through electrode 7 is required to penetrate only at least one of the plurality of layers so as to connect the coil portions to each other. The drive coil 8 may also have a plurality of through electrodes 7 in alternative aspects.

The first detection coil 6A is provided between the first layer 3 and the second layer 4. Therefore, the first detection coil 6A is provided on the first main surface 4a of the second layer 4 at the same time as being provided on the second main surface 3b of the first layer 3. Moreover, the second detection coil 6B is provided between the second layer 4 and the third layer 5. Therefore, the second detection coil 6B is provided on the first main surface 5a of the third layer 5 at the same time as being provided on the second main surface 4b of the second layer 4. The first detection coil 6A and the second detection coil 6B overlap each other in a plan view.

The multilayer substrate 2 is provided with a through hole 2d. More specifically, in the exemplary aspect, the through hole 2d is positioned at the center of the drive coil 8 and at the centers of the two-phase detection coils in a plan view. In alternative aspects, the position of the through hole 2d is not limited to that described above. Moreover, the through hole 2d is not necessarily needed to be provided in the multilayer substrate 2.

The present embodiment has a feature that the drive coil 8, and the first detection coil 6A and the second detection coil 6B are provided on respective different main surfaces, among the plurality of main surfaces of the plurality of layers in the multilayer substrate 2. This configuration enables a reduction of the size of the angle sensor 1. This will be described hereinafter, through comparison of the present embodiment with a comparative example.

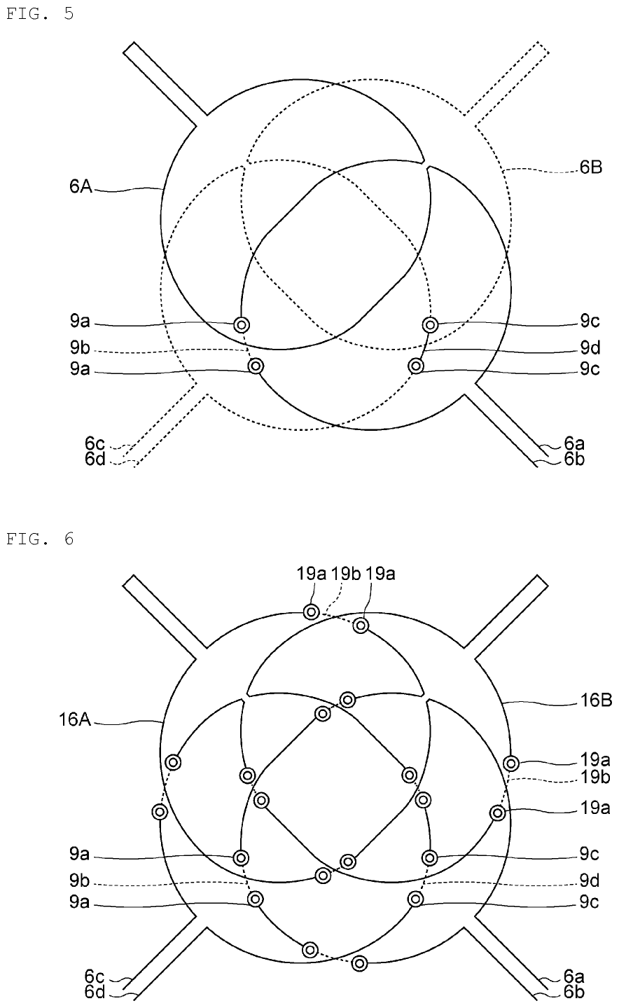

The comparative example illustrated in a simplified view in FIG. 4 is different from the first embodiment, in that a drive coil 108, and a first detection coil 106A and a second detection coil 106B are provided on the same main surface of the same layer in a multilayer substrate. In the comparative example, in order to avoid the drive coil 108 from coming into contact with the first detection coil 106A and second detection coil 106B, there is provided a gap between the drive coil 108 and the first detection coil 106A and the second detection coil 106B. This configuration provides for a large diameter of the drive coil 108.

In contrast, as illustrated in FIG. 1, in the first embodiment, the drive coil 8, and the first detection coil 6A and the second detection coil 6B are provided on respective different main surfaces, among the plurality of main surfaces of the plurality of layers in the multilayer substrate 2. This configuration enables placing the drive coil 8 and the first detection coil 6A and the second detection coil 6B such that they overlap each other in a plan view. Effectively, the drive coil 8 has a smaller diameter, which reduces the overall size.

Furthermore, in the comparative example illustrated in FIG. 4, a foreign substance may intrude into the gap between the drive coil 108 and the first detection coil 106A and the second detection coil 106B. At this time, in a case where thin wires are used for the respective coils in order to downsize the angle sensor, the wires may be disconnected due to contact of the wires with the foreign substance. In contrast, in the first embodiment, there is not provided a gap such as that in the comparative example, and, therefore, no foreign substance may intrude into such a gap. Therefore, if thin wires are used, these wires are less likely to be disconnected. Furthermore, it is possible to effectively downsize the angle sensor 1.

As illustrated in FIG. 2, according to the first embodiment, the innermost peripheral portion of the drive coil 8 is positioned at such a portion as to overlap the two-phase detection coils in a plan view. However, the innermost peripheral portion of the drive coil 8 may be also disposed in such a manner as to be in contact with the two-phase detection coils in a plan view. In this case, similarly, the angle sensor 1 can be downsized. On the other hand, according to the first embodiment, the outermost peripheral portion of the drive coil 8 is positioned outside the two-phase detection coils in a plan view. However, the outermost peripheral portion of the drive coil 8 may be also disposed in such a manner as to overlap the two-phase detection coils in a plan view. In this case, it is possible to further downsize the angle sensor 1.

In the present disclosure, the innermost peripheral portion and the outermost peripheral portion refer to the innermost peripheral portion and the outermost peripheral portion in a plan view. As illustrated in FIG. 1, when the drive coil 8 has a plurality of coil portions, the innermost peripheral portion of the drive coil 8 refers to the inner peripheral portion positioned at the innermost side, of the plurality of coil portions. Similarly, the outermost peripheral portion of the drive coil 8 refers to the outer peripheral portion positioned at the outermost side, of the plurality of coil portions. In the first embodiment, the inner peripheral portion of the first coil portion 8A is aligned with the inner peripheral portion of the second coil portion 8B in a plan view. The outer peripheral portion of the first coil portion 8A is aligned with the outer peripheral portion of the second coil portion 8B in a plan view. Therefore, the innermost peripheral portion and the outermost peripheral portion of the drive coil 8 are the inner peripheral portion and the outer peripheral portion of the first coil portion 8A and the second coil portion 8B.

Hereinafter, an exemplary structure of the present embodiment will be described. Preferably, the first detection coil 6A and the second detection coil 6B are provided on respective different main surfaces, among the plurality of the main surfaces of the plurality of layers in the multilayer substrate 2. This configuration eliminates the need for a through electrode for avoiding contact between the first detection coil 6A and the second detection coil 6B, which allows downsizing the angle sensor 1 more effectively. This will be described in detail, hereinafter.

FIG. 5 is a view illustrating the structure of electrodes of the first detection coil and the second detection coil according to the first embodiment. In FIG. 5, an electrode provided on the second main surface 4b of the second layer 4 is indicated by a broken line.

Portions of the wires of the first detection coil 6A are connected by a pair of through electrodes 9a and a connection electrode 9b. This configuration avoids the wires of the first detection coil 6A from coming in contact with each other. More specifically, the pair of through electrodes 9a penetrates the second layer 4 in the multilayer substrate 2. The paired through electrodes 9a are connected to each other by the connection electrode 9b. Incidentally, the connection electrode 9b is provided on the second main surface 4b of the second layer 4 and on the first main surface 5a of the third layer 5, but is not in contact with the second detection coil 6B.

Similarly, portions of the wires of the second detection coil 6B are connected by a pair of through electrodes 9c and a connection electrode 9d. This configuration avoids the wires of the second detection coil 6B from coming in contact with each other. More specifically, the pair of through electrodes 9c penetrates the second layer 4 in the multilayer substrate 2. The paired through electrodes 9c are connected to each other by the connection electrode 9d. Incidentally, the connection electrode 9d is provided on the second main surface 3b of the first layer 3 and on the first main surface 4a of the second layer 4, but is not in contact with the first detection coil 6A. On the other hand, as described above, there is no need for a through electrode to avoid contact between the first detection coil 6A and the second detection coil 6B. Therefore, in the first embodiment, it is necessary to provide only two pairs of through electrodes. This configuration reduces portions required for providing such through electrodes. Accordingly, the size of the angle sensor 1 can be reduced more effectively.

The first detection coil 6A has a connection portion 6a and a connection portion 6b. The connection portion 6a and the connection portion 6b according to the first embodiment are portions to be electrically connected to the outside. A signal is inputted through one of the connection portion 6a and the connection portion 6b, while a signal is outputted through the other. Similarly, the second detection coil 6B has a connection portion 6c and a connection portion 6d. A signal is inputted through one of the connection portion 6c and the connection portion 6d, while a signal is outputted through the other.

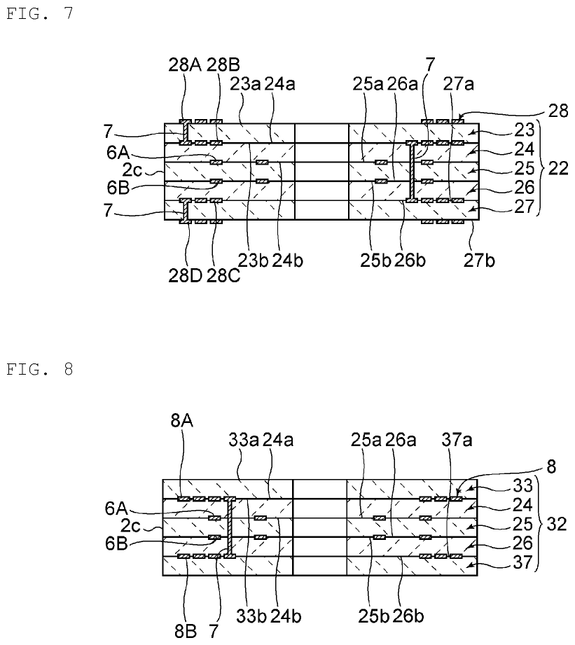

Incidentally, the two-phase detection coils may be also provided on the same main surface, among the plurality of main surfaces in the multilayer substrate 2. In a modification example illustrated in FIG. 6 according to the first embodiment, both a first detection coil 16A and a second detection coil 16B are provided on the second main surface 3b of the first layer 3 and on the first main surface 4a of the second layer 4. In the present modification example, similarly, in order to avoid contact between the wires of the first detection coil 16A and between the wires of the second detection coil 16B, there are provided two pairs of through electrodes and two connection electrodes. Further, in the present modification example, in order to avoid contact between the first detection coil 16A and the second detection coil 16B, there are eight pairs of through electrodes 19a and eight connection electrodes 19b. Namely, there are provided a total of 10 pairs of through electrodes and 10 connection electrodes.

In the present modification example, similarly to in the first embodiment, the drive coil 8, and the two-phase detection coils are provided on respective different main surfaces, among the plurality of main surfaces of the plurality of layers in the multilayer substrate 2. This enables placing the drive coil 8, the first detection coil 16A and the second detection coil 16B, such that they overlap each other in a plan view. This configuration allows the drive coil 8 to have a smaller diameter, thereby effectively reducing the size. Furthermore, the first detection coil 6A and the second detection coil 6B are preferably on respective different main surfaces, among the plurality of main surfaces of the plurality of layers in the multilayer substrate 2, as in the first embodiment. In this case, there is no need for the through electrodes 19a and the connection electrode 19b, which have been described above.

In an exemplary aspect, the drive coil 8 includes a plurality of coil portions. Furthermore, the plurality of coil portions is preferably provided on respective different main surfaces, among the plurality of main surfaces of the plurality of layers in the multilayer substrate 2, and also the plurality of coil portions overlap each other in a plan view. This configuration strengthens the magnetic field, without increasing the outer diameter of the drive coil 8. More specifically, for example, it is assumed that there is provided a single layered coil portion having 5 windings and an outer diameter of 10 mm, and this coil portion generates a magnetic field with a strength of about 0.525 pH. It is assumed that there are provided two such layered coil portions. Further, when the two layered coil portions are aligned with each other in a plan view, the magnetic field has a strength of about 2.02 pH. Further, in this example, the distance between the coil portions is set to 0.1 mm. As described above, by providing two layered coil portions, the strength of the magnetic field is increased about fourfold.

On the other hand, it is assumed that there is provided a single layered coil portion having 10 windings and an outer diameter of 10 mm, using the same wire as that of the aforementioned coil portion. This coil portion generates a magnetic field with a strength of about 1.92 pH. This reveals that the magnetic field can be strengthened more largely by providing a plurality of coil portions than by increasing the number of windings of a single coil portion.

In another example, it is assumed that there is provided a single layered coil portion having 2 windings and an outer diameter of 10 mm, and this coil portion generates a magnetic field with a strength of about 0.1 pH. It is assumed that there are provided two or four such layered coil portions. When the two layered coil portions are aligned with each other in a plan view, the magnetic field has a strength of about 0.364 pH. Further, when the four layered coil portions are aligned with each other in a plan view, the magnetic field has a strength of about 1.272 pH. Further, in these examples, the distance between the coil portions is set to 0.2 mm. From the aforementioned examples, it can be seen that, by providing two layered coil portions, the strength of the magnetic field can be increased about fourfold. Furthermore, it can be seen that, by providing four layered coil portions, it is possible to increase the strength of the magnetic field about tenfold. Therefore, the magnetic field can be strengthened, without increasing the outer diameter of the drive coil 8. Further, the drive coil 8 can have a smaller diameter for providing a magnetic field with a desired strength. This configuration can reduce the size of the angle sensor 1 more effectively.

Further, the first detection coil 6A and the second detection coil 6B are preferably provided between two layered coil portions among the plurality of coil portions. By doing this, it is possible to preferably detect an increase or decrease of the eddy current by the first detection coil 6A and the second detection coil 6B.

In an exemplary aspect, the plurality of layers in the multilayer substrate 2 is preferably made of a low-temperature co-fired ceramic (LTCC) or a glass ceramic. In this case, there is no need for etching in providing the multilayer substrate 2, which eliminates the necessity for providing a portion supposed to be etched. This enables downsizing the multilayer substrate 2 and the angle sensor 1 easily. Further, in providing the angle sensor 1, it is preferable to form a plurality of drive coils 8, a plurality of first detection coils 6A, and a plurality of second detection coils 6B in a large-sized multilayer substrate and, then, divide the aforementioned multilayer substrate. This process enables the providing of a plurality of angle sensors 1 at a time, thereby enhancing the productivity.

FIG. 7 is a schematic front elevational sectional view of an angle sensor according to a second exemplary embodiment.

The present embodiment is different from the first embodiment in that a multilayer substrate 22 includes five layers, a drive coil 28 has four layered coil portions, and a plurality of through electrodes 7 is provided. Along therewith, the placement of the respective coil portions and two-phase detection coils is also different from that of the first embodiment. Except for the aforementioned points, the angle sensor 1 according to the present embodiment has a similar structure to that of the angle sensor according to the first embodiment.

More specifically, the multilayer substrate 22 of the exemplary embodiment shown in FIG. 7 includes a first layer 23, a second layer 24, a third layer 25, a fourth layer 26, and a fifth layer 27. In the multilayer substrate 22, the first layer 23, the second layer 24, the third layer 25, the fourth layer 26, and the fifth layer 27 are stacked in this order. Each layer in the multilayer substrate 22 has a first main surface and a second main surface as similarly described above with respect to the first embodiment.

As shown, the drive coil 28 includes a first coil portion 28A, a second coil portion 28B, a third coil portion 28C, and a fourth coil portion 28D. The first coil portion 28A is provided on the first main surface 23a of the first layer 23. The second coil portion 28B is provided on the first main surface 24a of the second layer 24 at the same time as being provided on the second main surface 23b of the first layer 23. The third coil portion 28C is provided on the first main surface 27a of the fifth layer 27 at the same time as being provided on the second main surface 26b of the fourth layer 26. The fourth coil portion 28D is provided on the second main surface 27b of the fifth layer 27.

Moreover, the first coil portion 28A and the second coil portion 28B are connected to each other via a through electrode 7. Similarly, the second coil portion 28B and the third coil portion 28C, and the third coil portion 28C and the fourth coil portion 28D are also connected to each other via respective through electrodes 7.

The first detection coil 6A is provided on the first main surface 25a of the third layer 25 at the same time as being provided on the second main surface 24b of the second layer 24. The second detection coil 6B is provided on the first main surface 26a of the fourth layer 26 at the same time as being provided on the second main surface 25b of the third layer 25.

In the present embodiment, the drive coil 28, and the first detection coil 6A and the second detection coil 6B are provided on respective different main surfaces, among the plurality of main surfaces of the plurality of layers in the multilayer substrate 22. Further, the drive coil 28 has four layered coil portions that overlap each other in a plan view. This configuration reduces the size of the angle sensor 1 more effectively.

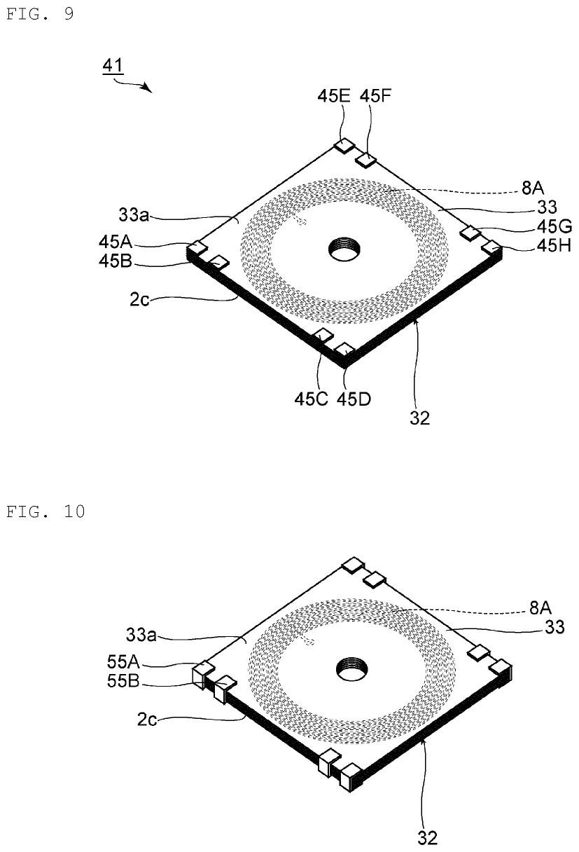

FIG. 8 is a schematic front elevational sectional view of an angle sensor according to a third exemplary embodiment.

The exemplary embodiment of FIG. 8 is different from the first embodiment in that a multilayer substrate 32 includes five layers, a pair of outermost layers in the multilayer substrate 32 forms a pair of protective layers, and a drive coil 8, a first detection coil 6A, and a second detection coil 6B are provided inside the pair of protective layers. Incidentally, the outermost layers are the layers at the outermost sides in the stacking direction of the multilayer substrate 32. In the multilayer substrate 32, the first layer is the first outermost layer and, also, is the first protective layer 33. The fifth layer is the second outermost layer and, also, is the second protective layer 37. Except for the aforementioned points, the angle sensor 1 according to the present embodiment has a similar structure to that of the angle sensor according to the first embodiment.

According to the exemplary aspect, a first coil portion 8A of the drive coil 8 is provided on the first main surface 24a of the second layer 24 at the same time as being provided on the second main surface 33b of the first protective layer 33. Moreover, a second coil portion 8B is provided on the first main surface 37a of the second protective layer 37 at the same time as being provided on the second main surface 26b of the fourth layer 26.

The first detection coil 6A is provided on the first main surface 25a of the third layer 25 at the same time as being provided on the second main surface 24b of the second layer 24. The second detection coil 6B is provided on the first main surface 26a of the fourth layer 26 at the same time as being provided on the second main surface 25b of the third layer 25.

In this manner, the drive coil 8, the first detection coil 6A, and the second detection coil 6B are provided inside the pair of protective layers. This configuration inhibits each coil from coming into contact with the outside, thereby inhibiting each coil from being damaged.

In an exemplary aspect, only a single protective layer may be provided. That is, the multilayer substrate 32 may have only the first protective layer 33, and is not required to have the second protective layer. In this case, the fifth layer forms the second outermost layer but does not form the second protective layer. It is necessary only to provide the drive coil 8, the first detection coil 6A, and the second detection coil 6B closer to the second outermost layer than to the first outermost layer as the first protective layer 33. In this case, similarly, it is possible to inhibit each coil from coming into contact with the outside, thereby inhibiting each coil from being damaged. The aforementioned example is suitable, for example, when the first protective layer 33 side is brought close to the target.

In the present embodiment, similarly, the drive coil 8, the first detection coil 6A and the second detection coil 6B are provided on respective different main surfaces, among the plurality of main surfaces of the plurality of layers in the multilayer substrate 32. This configuration reduces the size of the angle sensor effectively.

FIG. 9 is a perspective view of an angle sensor according to a fourth exemplary embodiment.

The exemplary embodiment of FIG. 9 is different from the third embodiment in that a plurality of electrode lands is provided on a first main surface 33a of a first protective layer 33. Except for the aforementioned points, the angle sensor 41 according to the present embodiment has a similar structure to that of the angle sensor according to the third embodiment.

More specifically, the plurality of electrode lands include a first electrode land 45A, a second electrode land 45B, a third electrode land 45C, a fourth electrode land 45D, a fifth electrode land 45E, a sixth electrode land 45F, a seventh electrode land 45G, and an eighth electrode land 45H. The angle sensor 41 is mounted on, for example, a mounting substrate and is electrically connected to the mounting substrate through the plurality of electrode lands.

The first electrode land 45A is electrically connected to the connection portion 6a of the first detection coil 6A illustrated in FIG. 5. Similarly, the second electrode land 45B is electrically connected to the connection portion 6b of the first detection coil 6A. The first electrode land 45A and the second electrode land 45B form a first external connection electrode in the present invention. In the present embodiment, a signal is inputted through the first electrode land 45A, and a signal is outputted through the second electrode land 45B. The first electrode land 45A and the connection portion 6a may be also connected to each other by, for example, a through electrode or the like. It is noted that the same applies to the connection between the other electrode lands and the coils.

The third electrode land 45C is electrically connected to the connection portion 6c of the second detection coil 6B. The fourth electrode land 45D is electrically connected to the connection portion 6d of the second detection coil 6B. The third electrode land 45C and the fourth electrode land 45D form a second external connection electrode in the present invention. In the present embodiment, a signal is inputted through the third electrode land 45C, and a signal is outputted through the fourth electrode land 45D.

The fifth electrode land 45E is electrically connected to an input-side connection portion of the drive coil 8. The sixth electrode land 45F is electrically connected to an output-side connection portion of the drive coil 8. The fifth electrode land 45E and the sixth electrode land 45F form a third external connection electrode in the present invention. On the other hand, the seventh electrode land 45G and the eighth electrode land 45H are not connected to the drive coil 8, the first detection coil 6A, and the second detection coil 6B. The seventh electrode land 45G and the eighth electrode land 45H form a fourth external connection electrode in the present invention.

In the exemplary aspect, the angle sensor 41 has the plurality of electrode lands and, therefore, can be preferably mounted on a mounting substrate or the like. In the present embodiment, two electrode lands are uniformly placed at each of the four corners of a multilayer substrate 32 in a plan view. This configuration enables stably mounting the angle sensor 41. However, it is noted that the placement of the plurality of electrode lands is not limited to that described above.

In the present embodiment, similarly, the drive coil 8, the first detection coil 6A and the second detection coil 6B are provided on respective different main surfaces, among the plurality of main surfaces of the plurality of layers in the multilayer substrate 32. This configuration reduces the size the angle sensor 41 effectively.

Incidentally, the first to fourth external connection electrodes are not limited to electrode lands. Hereinafter, there will be described a first modification example and a second modification example according to the fourth embodiment, which are different from the fourth embodiment in terms of the structure of first to fourth external connection electrodes. In the first modification example and the second modification example, similarly, it is possible to effectively downsize the angle sensor, and it is also possible to preferably mount the angle sensor on a mounting substrate or the like.

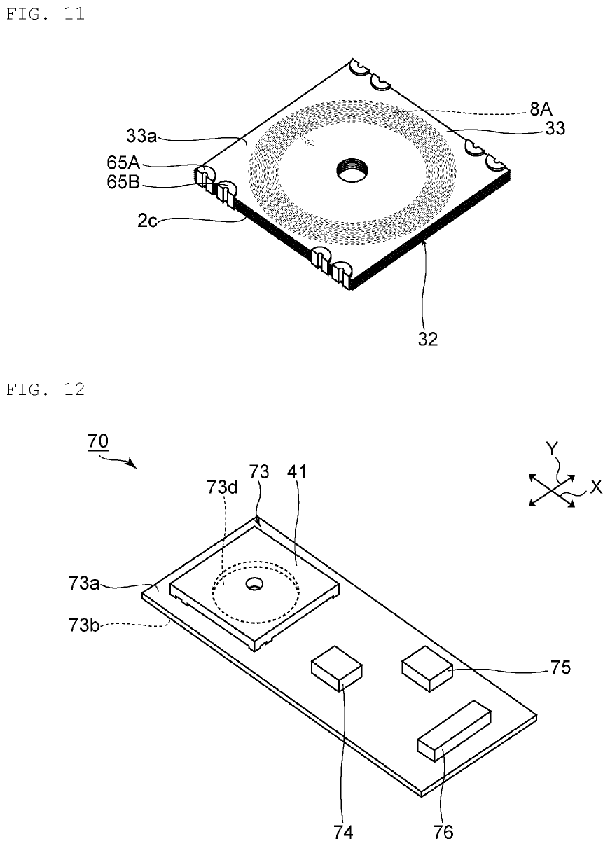

In the first modification example illustrated in FIG. 10, a first external electrode 55A and a second external electrode 55B as a first external connection electrode are provided on one main surface, a side surface 2c, and the other main surface of a multilayer substrate 32. Second to fourth external connection electrodes are also provided in the same manner.

In the second modification example illustrated in FIG. 11, a first half through hole electrode 65A and a second half through hole electrode 65B as a first external connection electrode are provided on one main surface, a side surface 2c, and the other main surface of a multilayer substrate 32. Second to fourth external connection electrodes are also provided in the same manner. Incidentally, the angle sensor according to the present invention may be also electrically connected to the mounting substrate by, for example, a wire or the like, when the angle sensor is not provided with the aforementioned respective external connection electrodes.

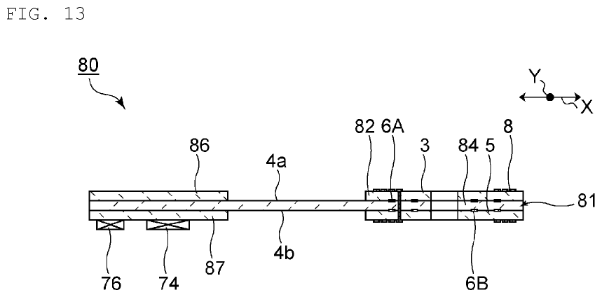

FIG. 12 is a perspective view of an angle sensor module according to a fifth exemplary embodiment.

According to the exemplary aspect, the angle sensor module 70 includes a mounting substrate 73 and an angle sensor 41. In particular, the angle sensor 41 in the angle sensor module 70 has a portion different from that of the fourth embodiment, in terms of the placement of a plurality of electrode lands. However, the angle sensor 41 is denoted by the same reference numeral as that of the fourth embodiment. Incidentally, the angle sensor used in the angle sensor module 70 is not limited to the angle sensor 41, and may be any angle sensor according to the present disclosure.

The mounting substrate 73 has a third main surface 73a and a fourth main surface 73b that face each other. As further shown, the mounting substrate 73 has a rectangular shape in a plan view. More specifically, the mounting substrate 73 has a first direction X and a second direction Y. The first direction X and the second direction Y are orthogonal to each other. The dimension of the mounting substrate 73 along the first direction X is larger than the dimension thereof along the second direction Y. However, the shape of the mounting substrate 73 in a plan view is not limited to that described above, and may be, for example, a polygon other than a rectangle, a circle, an ellipse, or the like.

The angle sensor 41 is provided on the third main surface 73a of the mounting substrate 73. A plurality of electrode lands in the angle sensor 41 is electrically connected to the mounting substrate 73. The mounting substrate 73 is provided with a through hole 73d. Through hole 73d is matched with the angle sensor 41 in a plan view. The through hole 73d is provided in such a way as to allow a target to pass therethrough. This enables bringing the target close to the angle sensor 41 through the fourth main surface 73b of the mounting substrate 73. However, it is not necessary to provide the through hole 73d. In this case, the target may be brought close to the angle sensor 41 in a state where the third main surface 73a is oriented toward the target, for example.

The angle sensor module 70 includes an angle detection circuit 74, a control circuit 75, and a connector 76. The angle detection circuit 74, the control circuit 75, and the connector 76 are provided on the third main surface 73a of the mounting substrate 73. More specifically, the angle detection circuit 74, the control circuit 75, and the connector 76 are placed in such a way as to overlap the angle sensor 41 when viewed along the first direction X. However, it is noted that the placement of the angle detection circuit 74, the control circuit 75, and the connector 76 is not limited to that described above. In other exemplary aspect, the connector 76 connects at least one of the angle sensor 41, the angle detection circuit 74, and the control circuit 75 to the outside.

The angle detection circuit 74 can be formed by an angle detection IC in the present embodiment, although not particularly limited. The angle detection circuit 74 is electrically connected to the angle sensor 41. Signals from two-phase detection coils in the angle sensor 41 are inputted to the angle detection circuit 74. Based on these signals, the angle detection circuit 74 is configured to detect the rotational angle of the target. In the angle sensor module 70, the angle sensor 41 and the angle detection circuit 74 are integrated. This configuration enables downsizing the entire system for angle detection. However, the angle sensor module 70 is not necessarily required to include the angle detection circuit 74. In this case, the angle sensor 41 may be electrically connected to an external angle detection circuit.

The control circuit 75 is a control circuit for an appliance incorporating the target. In the angle sensor module 70, the angle sensor 41 and the control circuit 75 are integrated. This configuration enables downsizing the entire system for angle detection, which includes the control circuit 75 for an object to be subjected to the rotational angle detection. However, the angle sensor module 70 is not necessarily required to include the control circuit 75.

An LC oscillation circuit for a drive coil 8 in the angle sensor 41 may be also provided on the mounting substrate 73. In this case, similarly, the entire system for angle detection can be downsized.

Furthermore, since the angle sensor 41 can be downsized as described above, the mounting substrate 73 can be downsized. This can downsize the angle sensor module 70 more effectively.

The mounting substrate 73 may also be formed by a flexible substrate that can include, for example, a resin such as polyimide. In this case, the mounting substrate 73 can be bent, which enables further downsizing the angle sensor module 70.

FIG. 13 is a simplified sectional view of an angle sensor module according to a sixth exemplary embodiment. In FIG. 13, an angle detection circuit 74 and a connector 76 are illustrated by a simplified view of rectangular shapes each provided with two diagonal lines.

The present embodiment is different from the fifth embodiment in terms of the mounting substrate and the structure of an angle sensor 81. More specifically, the mounting substrate for the angle sensor module 80 is integrated with a second layer 84 in a multilayer substrate 82 in the angle sensor 81. Thus, the angle sensor 81 is structured to include the mounting substrate as the second layer 84. Except for the aforementioned points, the angle sensor 81 according to the present embodiment has a similar structure to that of the angle sensor 1 according to the first embodiment. Further, except for the aforementioned points, the angle sensor module 80 according to the present embodiment has a similar structure to that of the angle sensor module 70 according to the fifth embodiment.

The dimension of the second layer 84 along a first direction X is larger than the dimensions of the first layer 3 and the third layer 5 along the first direction X. Therefore, the second layer 84 has a portion which does not overlap the first layer 3 and the third layer 5 in a plan view. In this portion, the angle detection circuit 74, the connector 76 and the like are provided. Although not illustrated, in this portion, a control circuit 75 similar to that of the fifth embodiment is also provided.

More specifically, a first layer-form body 86 is provided in the portion of the first main surface 4a of the second layer 84, which does not overlap the first layer 3 in a plan view. A second layer-form body 87 is provided in the portion of the second main surface 4b of the second layer 84, which does not overlap the third layer 5 in a plan view. On the second layer-form body 87, the angle detection circuit 74, the connector 76 and the like are provided. The first layer-form body 86 and the second layer-form body 87 may be formed by either a member including a single layer or a body including laminated layers. However, it is not necessarily necessary to provide the first layer-form body 86 and the second layer-form body 87. The angle detection circuit 74, the connector 76, and the like may be also provided directly on the first main surface 4a or the second main surface 4b of the second layer 84.

In the present embodiment, similarly, a drive coil 8, a first detection coil 6A and a second detection coil 6B are provided on respective different main surfaces, among the plurality of main surfaces of the plurality of layers in the multilayer substrate 82. This configuration can reduce the size of the angle sensor 81 more effectively. Furthermore, since the angle sensor 81 includes the mounting substrate as the second layer 84, the mounting substrate can be also further downsized. This configuration can further reduce the size of the angle sensor module 80 more effectively.

### DESCRIPTION OF REFERENCE SYMBOLS

1: Angle sensor
2: Multilayer substrate
2c: Side surface
2d: Through hole
3 to 5: First to third layers
3a to 5a: First main surface
3b to 5b: Second main surface
6A, 6B: First and second detection coils
6a to 6d: Connection portion
7: Through electrode
8: Drive coil
8A, 8B: First and second coil portions
9a: Through electrode
9b: Connection electrode
9c: Through electrode
9d: Connection electrode
16A, 16B: First and second detection coils
19a: Through electrode
19b: Connection electrode
22: Multilayer substrate
23 to 27: First to fifth layers
23a to 27a: First main surface
23b to 27b: Second main surface
28: Drive coil
28A to 28D: First to fourth coil portions
32: Multilayer substrate
33: First protective layer
33a, 33b: First and second main surfaces
37: Second protective layer
37a: First main surface
41: Angle sensor
45A to 45H: First to eighth electrode lands
55B: First and second external electrodes
65B: First and second half through hole electrodes
70: Angle sensor module
73: Mounting substrate
73a, 73b: Third and fourth main surfaces
73d: Through hole
74: Angle detection circuit
75: Control circuit
76: Connector
80: Angle sensor module
81: Angle sensor
82: Multilayer substrate
84: Second layer
86, 87: First and second layer-form bodies
100: Target
102: Rotatable shaft
106A, 106B: First and second detection coils
108: Drive coil

1. An angle sensor comprising:
a multilayer substrate having a plurality of layers that each have main surfaces that face each other;
a drive coil disposed in the multilayer substrate; and
two-phase detection coils disposed in the multilayer substrate,
wherein the drive coil and the two-phase detection coils are disposed on different main surfaces, respectively, of the main surfaces of the plurality of layers.

2. The angle sensor according to claim 1, wherein the drive coil and the two-phase detection coils overlap each other in a plan view.

3. The angle sensor according to claim 1, wherein the two-phase detection coils are disposed on different main surfaces, respectively, of the main surfaces of the plurality of layers, and the two-phase detection coils overlap each other in a plan view.

4. The angle sensor according to claim 1, wherein the drive coil includes a plurality of coil portions and a through electrode.

5. The angle sensor according to claim 4, wherein the plurality of coil portions is on different main surfaces, respectively, of the main surfaces of the plurality of layers, and the plurality of coil portions overlap each other in a plan view.

6. The angle sensor according to claim 5, wherein the through electrode extends through at least one layer of the plurality of layers so as to connect the coil portions to each other.

7. The angle sensor according to claim 6, wherein the two-phase detection coils are disposed between two layered coil portions among the plurality of coil portions.

8. The angle sensor according to claim 1, wherein the plurality of layers in the multilayer substrate includes a first outermost layer and a second outermost layer, and the drive coil and the two-phase detection coils are disposed closer to the second outermost layer than to the first outermost layer.

9. The angle sensor according to claim 8, wherein the drive coil and the two-phase detection coils are disposed between the first outermost layer and the second outermost layer.

10. The angle sensor according to claim 1, wherein each of the plurality of layers comprises a low-temperature co-fired ceramic or a glass ceramic.

11. The angle sensor according to claim 1, further comprising:
a first external connection electrode on the multilayer substrate and electrically connected to a first detection coil of the two-phase detection coils;
a second external connection electrode on the multilayer substrate and electrically connected to a second detection coil of the two-phase detection coils; and
a third external connection electrode on the multilayer substrate and electrically connected to the drive coil.

12. The angle sensor according to claim 1,
wherein the plurality of layers includes a first layer having first and second opposing main surfaces and a second layer having first and second opposing main surfaces, and
wherein the drive coil is disposed on the first main surface of the first layer and at least one of the two-phase detection coils is disposed on the second main surface of the first layer and the first main surface of the second layer.

13. The angle sensor according to claim 12, wherein the second main surface of the first layer and the first main surface of the second layer are directly coupled to each other.

14. An angle sensor comprising:
a multilayer substrate having at least a first layer with opposing first and second main surfaces and a second layer with opposing first and second main surfaces, with the first main surface of the second layer being directly coupled to the second main surface of the first layer;
a drive coil disposed on the first main surface of the first layer; and
two-phase detection coils disposed in the multilayer substrate and on the first main surface of the second layer and the second main surface of the first layer.

15. The angle sensor according to claim 14, wherein the drive coil and the two-phase detection coils overlap each other in a plan view.

16. The angle sensor according to claim 14, wherein:
the drive coil includes a plurality of coil portions and a through electrode,
the plurality of coil portions is on different main surfaces, respectively, of the first and second layers, and the plurality of coil portions overlap each other in a plan view, and
the through electrode extends through at least one layer of the multilayer substrate so as to connect the coil portions to each other.

17. The angle sensor according to claim 14, wherein the multilayer substrate includes a first outermost layer and a second outermost layer, and the drive coil and the two-phase detection coils are disposed closer to the second outermost layer than to the first outermost layer.

18. The angle sensor according to claim 17, wherein the drive coil and the two-phase detection coils are disposed between the first outermost layer and the second outermost layer.

19. The angle sensor according to claim 14, further comprising:
a first external connection electrode on the multilayer substrate and electrically connected to a first detection coil of the two-phase detection coils;
a second external connection electrode on the multilayer substrate and electrically connected to a second detection coil of the two-phase detection coils; and
a third external connection electrode on the multilayer substrate and electrically connected to the drive coil.

20. An angle sensor module comprising:
a mounting substrate;
the angle sensor according to claim 1, the angle sensor disposed on the mounting substrate; and
an angle detection circuit disposed on the mounting substrate and electrically connected to the angle sensor.
